(19) United States
(12) Patent Application Publication
(10) Pub. No.: US 2025/0252979 A1
(43) Pub. Date: Aug. 7, 2025

(54) CONTROLLING DATA CIRCUITRY POWER STATES

(71) Applicant: Micron Technology, Inc., Boise, ID (US)

(72) Inventors: Jose Rey De Luna, Boise, ID (US); Leonid Minz, Beer Sheva (IL); Ali Feiz Zarrin Ghalam, Sunnyvale, CA (US); Jeff Yu, Fremont, CA (US); Anna Chiara Siviero, Albignasego (PD) (IT); Tommaso Centro, Padova (PD) (IT); Luigi Pilolli, L’Aquila (IT)

(21) Appl. No.: 19/039,338

(22) Filed: Jan. 28, 2025

Related U.S. Application Data
(60) Provisional application No. 63/627,863, filed on Feb. 1, 2024.

(51) Int. Cl. G11C 5/14; G11C 7/10

(52) U.S. Cl. CPC G11C 5/148; G11C 7/1048

(57) ABSTRACT

A memory device includes processing logic to perform operations including receiving a data (DQ) circuitry activation command via a command address (CA) bus operatively coupled with CA circuitry of the memory device, wherein the DQ circuitry activation command includes data identifying a die of the memory device, in response to receiving the DQ circuitry activation command, causing DQ circuitry of the memory device to transition from a standby state to an idle state, receiving, via the CA bus, a data transaction initialization command of a data transaction, and in response to receiving the data transaction initialization command, causing the DQ circuitry to transition from the idle state to an active state.

### REFERENCE TO RELATED APPLICATION

This application claims the priority benefit of U.S. Provisional Patent Application No. 63/627,863, filed Feb. 1, 2024, the entirety of which is incorporated herein by reference.

### TECHNICAL FIELD

Embodiments of the disclosure relate generally to memory sub-systems, and more specifically, relate to controlling data (DQ) circuitry power states using a separate command address (SCA) protocol.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, in accordance with some embodiments of the present disclosure.

FIG. 1B is a block diagram of a memory device in communication with a memory sub-system controller of a memory sub-system, in accordance with some embodiments of the present disclosure.

FIGS. 2A-2C are diagrams of example systems that can be used to control data (DQ) circuitry power states using a separate command address (SCA) protocol, in accordance with some embodiments of the present disclosure.

FIG. 3 is a diagram illustrating an example implementation of controlling data (DQ) circuitry power states using a separate command address (SCA) protocol, in accordance with some embodiments of the present disclosure.

FIGS. 4A-4B are flow diagrams of example methods to control data (DQ) circuitry power states using a separate command address (SCA) protocol, in accordance with some embodiments of the present disclosure.

FIG. 5 is a block diagram of an example computer system in which embodiments of the present disclosure may operate.

### DETAILED DESCRIPTION

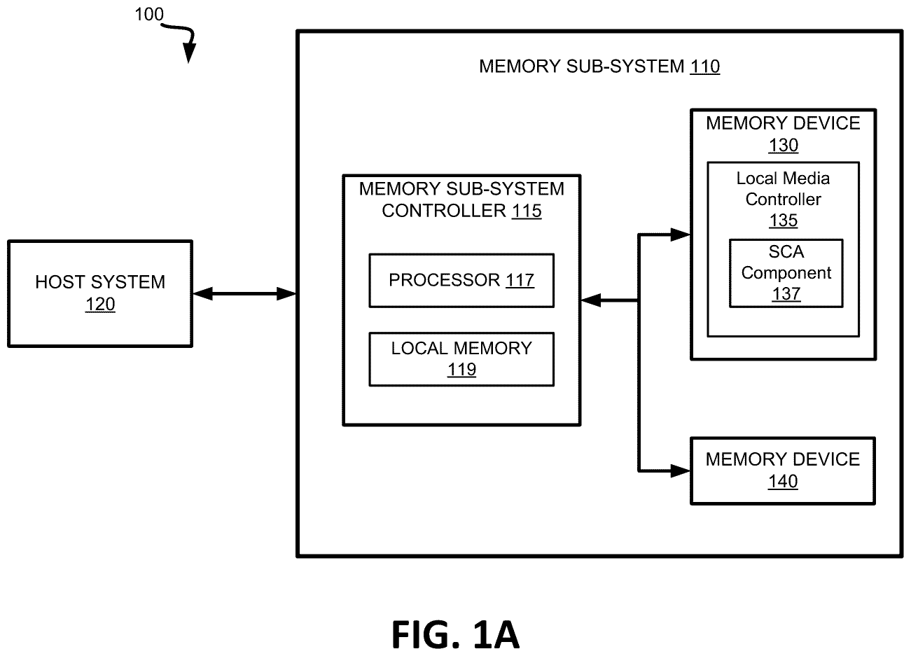

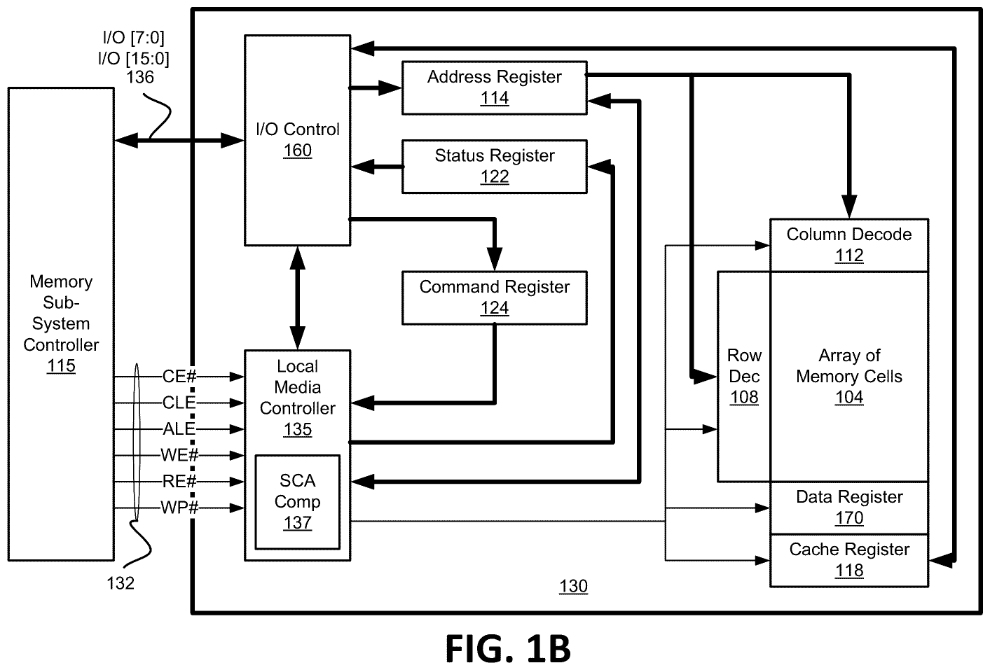

Aspects of the present disclosure are directed to controlling data (DQ) circuitry power states using a separate command address (SCA) protocol. A memory sub-system can be a storage device, a memory module, or a combination of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIGS. 1A-1B. A non-volatile memory device is a package of one or more dies. Each die can include one or more planes. For some types of non-volatile memory devices (e.g., NAND devices), each plane includes a set of physical blocks. Each block includes a set of pages. Each page includes a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

A memory sub-system can include an interface, between a memory sub-system controller and one or more memory devices, that can process multiple different signals relating to one or more transfers or communications with the one or more memory devices. The interface can utilize a set of command pins to implement interface protocols. For example, the set of command pins can include a Chip Enable (CE #) pin and a ready/busy (RB #) pin that monitors device status and indicates the completion of a memory access operation (e.g., whether the memory device is ready or busy). The “#” notation indicates that the CE #pin and the RB #pin are active when set to a logical low state (e.g., 0 V), also referred to as “active-low” pins. This in contrast to “active-high” pins, which are pins that are active when set to a logical high state (e.g., greater than 0 V). Asserting a pin can include setting the logical state of the pin to its active logical state, and de-asserting a pin can include setting the logical state of the pin to its inactive logical state. For example, an active-high pin is asserted when set to a logical high state (“driven high”) and de-asserted when set to a logical low state (“driven low”), while an active-low pin is asserted when to set to a logical low state (“driven low”) and de-asserted when set to a logical high state (“driven high”). For example, when the CE #pin is asserted and the memory device is not in a busy state, then the memory device can accept command, data and address information. When the memory device is not performing an operation, the CE #pin can be de-asserted.

A die of a memory device can include command address (CA) circuitry to receive command transactions (e.g., command sequences) from a memory sub-system controller via a CA bus representing a set of CA lines. The CA bus is an m-bit bus, which can be represented by CA[m−1:0], where “m−1” refers to the most significant bit of a range of m bits and “0” represents the least significant bit of the range of m bits. In some implementations, the CA bus is a two-bit bus, which can be represented by CA[1:0]. A die can further include data (DQ) circuitry to receive data transactions from the memory sub-system controller via a DQ bus representing a set of DQ lines. The DQ bus is an n-bit bus, which can be represented by DQ[n−1:0], where “n−1” refers to the most significant bit of a range of n bits and “0” represents the least significant bit of the range of n bits. In some implementations, the DQ bus is an eight-bit bus, which can be represented by DQ[7:0]. The CA and DQ circuitry can each include a comparator, voltage supply generators, reference generators, an amplifier, analog-to-digital converter, a buffer, latch circuitry and combination logic circuitry.

In some implementations, multiples dies are connected to the same CE #pin. Such implementations can reduce the number of CE #pins on the memory sub-system controller and signals that need to be routed, which can reduce production costs. When the memory sub-system controller wants to access a particular die at a particular time, the memory sub-system controller asserts a shared CE #signal via the CE #pin. Upon asserting the shared CE #signal via the CE #pin, the shared CE #signal causes all dies connected to the CE #pin to transition from a standby state to an idle state. The idle state is a higher power state in which a die is awaiting data transactions to be received from the memory sub-system controller via the DQ bus.

However, such implementations can be power-inefficient. For example, since the memory sub-system controller may only need to access a single die at a particular time, the other dies that have transitioned to the idle state due to the shared CE #signal are needlessly consuming power while in the idle state. As another example, a single type of transaction (e.g., command transaction or data transaction) is being sent from the memory sub-system controller to a die at a particular time. However, a CE #signal received by a die from a memory sub-system controller can cause both the CA circuitry and the DQ circuitry of the die to be enabled, even though either the CA circuitry or the DQ circuitry handles the command transaction or the data transaction, respectively. Accordingly, causing both CA circuitry and the DQ circuitry of a die to be enabled as a result of the same CE #signal, to handle a single type of transaction, can result in unnecessary die power consumption.

Aspects of the present disclosure address the above and other deficiencies by controlling DQ circuitry power states using a separate command address (SCA) protocol, which can increase die power efficiency. An SCA protocol described herein logically separates a CA bus from a DQ bus, such that only the CA circuitry of a die (and not the DQ circuitry) is enabled by the CE #signal. Instead of DQ circuitry of a die being enabled by the CE #signal, the SCA protocol allows the DQ circuitry to be separately controlled by command packets received by the die from the memory sub-system controller via the CA bus.

More specifically, an SCA protocol described herein implements a power control scheme to control the power state of DQ circuitry of one or more dies of a memory device. In the power control scheme, the DQ circuitry of each die can power-up in the standby state.

The memory sub-system controller can issue, via the CA bus, at least one DQ circuitry activation command (“activation command”) to DQ circuitry of at least one target die. In some implementations, the at least one target die is a single target die of a particular memory device. In some implementations, the at least one target die includes multiple target dies. In some implementations, the multiple target dies are within the same memory device. In some implementations, at least one target die is included in one memory device, and at least one target die is included in another memory device. Each activation command activates (e.g., wakes up) DQ circuitry of a respective target die, which transitions the DQ circuitry from the standby state to the idle state. Each activation command can include data identifying the respective target die (e.g., an address designating the respective target die). The amount of time that it takes for the data circuitry (e.g., DQ circuitry) of a target die to transition from the standby state to the idle state is referred to as the “activation time.” During the activation time, the memory sub-system controller can cause other commands to be sent to any non-target die(s) via the CA bus, which can further improve memory sub-system efficiency. In some implementations, causing the other commands to be sent to any non-target die(s) includes interleaving the other commands using command sequence interleaving (e.g., as opposed to sequentially issuing the commands).

Once DQ circuitry of a target die has transitioned to the idle state after receiving a data circuitry activation command, the target die can support an actual data transaction at a shorter latency than in the standby state. In some implementations, the data transaction is a data burst transaction. The receipt of the data transaction transitions the DQ circuitry of the target die from the idle state to an active state. The memory sub-system controller can issue the activation command to the target die via the CA bus in advance of the data transaction being issued to the target die via the DQ bus. After termination of the data transaction, the DQ circuitry of the target die can automatically transition back to the standby state from the active state.

A data transaction can be controlled by the memory sub-system controller using pre-defined data transaction control packets to initiate, pause, resume, or terminate the data transaction. For example, the data transaction can include an initiate transaction packet indicating the beginning of the data transaction, and a terminate transaction packet indicating the end of the data transaction. In some implementations, the data transaction further includes a pause transaction packet to cause the data transaction to pause and/or a resume transaction packet to cause the data transaction to resume after a pause. In some implementations, the data transaction control packets include are defined by Joint Electron Device Engineering Council (JEDEC) standards. For example, the initiate transaction packet and the resume transaction packet can each be implemented using a select chip enable (SCE) packet, the terminate transaction packet can be implemented using select chip terminate (SCT) packet, and the pause transaction packet can be implemented using a select chip pause (SCP) packet. Further details regarding controlling DQ circuitry power states using an SCA protocol will now be described below with reference to FIGS. 1A-5.

Advantages of the present disclosure include, but are not limited to, improved memory device performance and resource efficiency. For example, implementations described herein can enable a memory sub-system controller to selectively activate DQ circuitry of at least one target die using a DQ circuitry activation command separate from the CE #signal. As another example, implementations described herein can enable flexibility to issue the DQ circuitry activation command ahead of time, which can enable command sequence interleaving to non-target die(s) during the activation time. As yet another example, implementations described herein can, after termination of a data transaction handled by a target die, automatically cause the data circuitry of the target die to be placed into the standby state.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory device 130) when the memory sub-system 110 is coupled with the host system 120 by the physical host interface (e.g., PCIe bus or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

The memory device 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory device 130 can be grouped as pages that can refer to a logical unit of the memory device used to store data. With some types of memory (e.g., NAND), pages can be grouped to form blocks.

Although non-volatile memory components such as NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory device 130. The memory sub-system controller 115 can further include host interface circuitry to communicate with the host system 120 via the physical host interface. The host interface circuitry can convert the commands received from the host system into command instructions to access the memory device 130 as well as convert responses associated with the memory device 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130.

In some embodiments, the memory device 130 includes local media controller 135 that operates in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some embodiments, memory sub-system 110 includes a managed memory device, which includes a raw memory device 130 having control logic (e.g., local controller 132) on the die and a controller (e.g., memory sub-system controller 115) for media management within the same memory device package. An example of a managed memory device is a managed NAND (MNAND) device.

The memory sub-system 110 includes separate command address (SCA) component 137 that can be used to control DQ circuitry power states of at least one die of at least one memory device (e.g., memory device 130) using an SCA protocol. In some embodiments, local media controller 135 includes at least a portion of SCA component 137 and is configured to perform the functionality described herein. In some embodiments, the memory sub-system controller 115 includes at least a portion of SCA component 137. In some embodiments, SCA component 137 is part of the host system 120, an application, or an operating system. Further details regarding SCA component 137 and controlling data circuitry power states of memory devices using a separate command address protocol will be described below with reference to FIGS. 1B-5.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 112 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 112 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 112 to control the row decode circuitry 108 and column decode circuitry 112 in response to the addresses. In one embodiment, local media controller 135 includes the SCA component 137, which can implement the defect detection described herein during an erase operation on memory device 130.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 170 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 170 to the cache register 118. The cache register 118 and/or the data register 170 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 170 for programming the array of memory cells 104.

In an embodiment, cache register 118 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

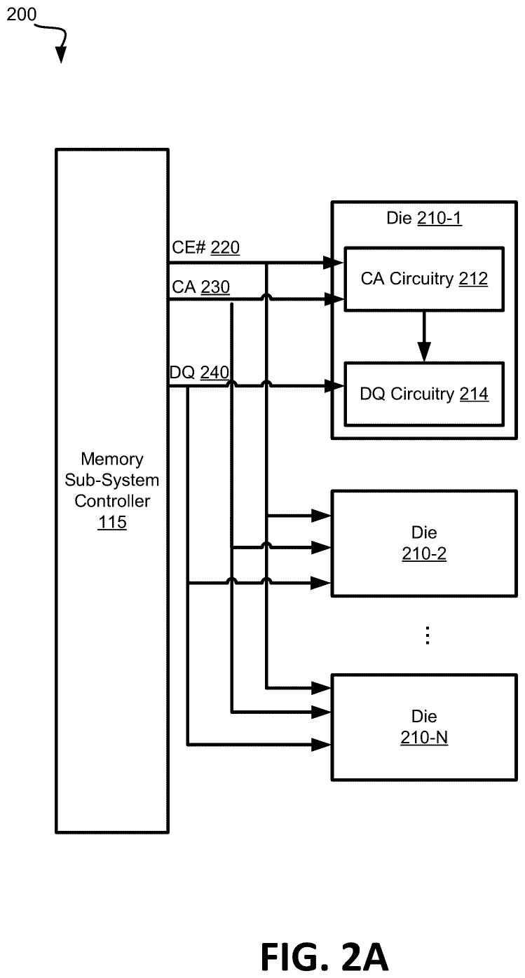

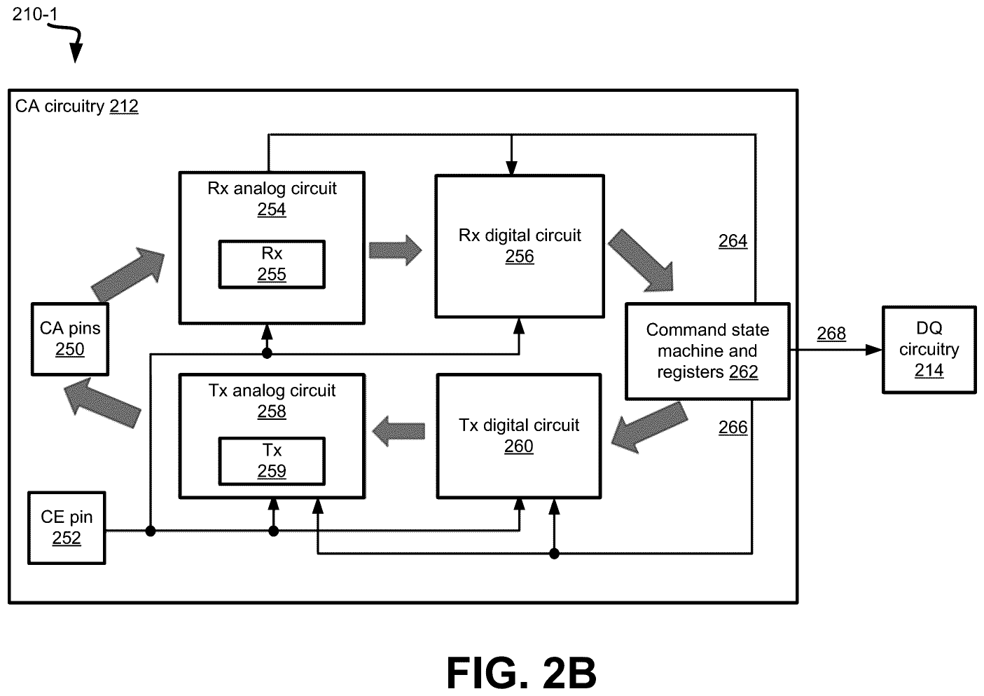

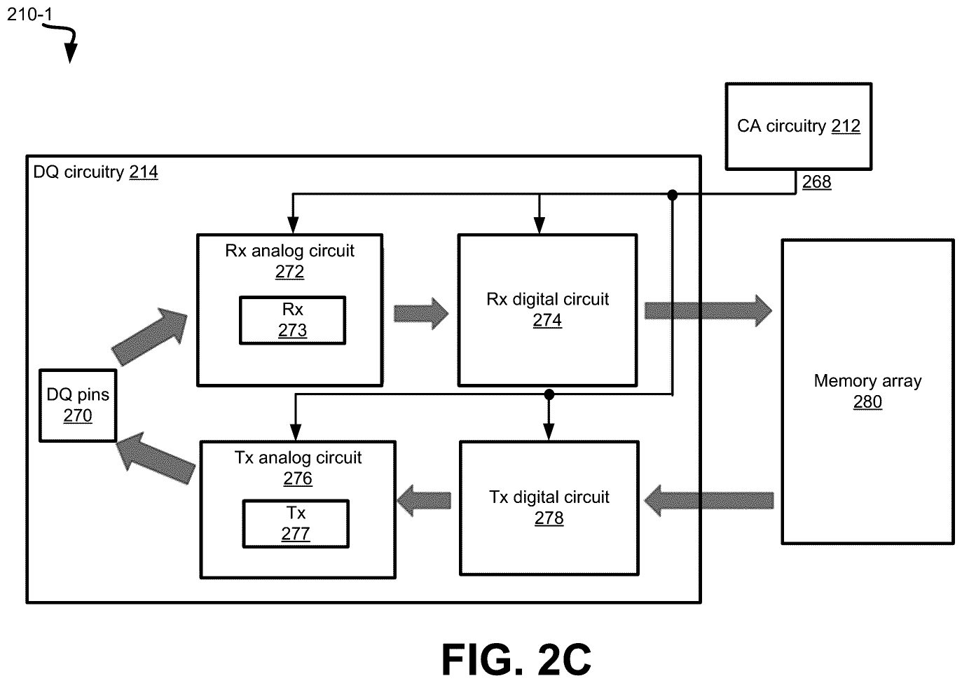

FIG. 2A is a diagram of a system 200 that can be used to control DQ circuitry power states using an SCA protocol, in accordance with some embodiments of the present disclosure. For example, system 200 can correspond to memory sub-system 110 of FIG. 1A.

As shown, system 200 includes memory sub-system controller 115 of FIGS. 1A-1B, and multiple dies 210-1 through 210-N. The number of dies, N, should not be considered limiting. In some implementations, each of dies 210-1 through 210-N is included in the same memory device (e.g., memory device 130 of FIGS. 1A-1B). In some implementations, at least one of dies 210-1 through 210-N is included in a first memory device and at least one of dies 210-1 through 210-N is included in a second memory device different from the first memory device.

Die 210-1 includes CA circuitry 212 and DQ circuitry 214. Although only shown with respect to die 210-1, each of the other dies 210-2 through 210-N can include CA circuitry and DQ circuitry similar to CA circuitry 212 and DQ circuitry 214, respectively. Further details regarding CA circuitry 212 and DQ circuitry 214 will be described below with reference to FIGS. 2B-2C.

System 200 can further include at least one CE #pin 220 connected, via one or more electrically conductive lines, with dies 210-1 through 210-N. At least one CE #pin 220 can be used to transmit a CE #signal from memory sub-system controller 115 to dies 210-1 through 210-N. For example, for each of dies 210-1 through 210-N, the CE #signal can be received by the respective CA circuitry. That is, only CA circuitry of a die may be enabled by the CE #signal.

System 200 can further include CA bus 230. CA bus 230 can be used to transmit command transactions from memory sub-system controller 115 to respective CA circuitry of dies 210-1 through 210-N (e.g., CA circuitry 212 of die 210-1). CA bus 230 is an m-bit bus, which can be represented by CA[m−1:0], where “m−1” refers to the most significant bit of a range of m bits and “0” represents the least significant bit of the range of m bits. In some implementations, CA bus 230 is a two-bit bus, which can be represented by CA[1:0].

System 200 can further include DQ bus 240. DQ bus 240 can be used to transmit data transactions from memory sub-system controller 115 to respective DQ circuitry of dies 210-1 through 210-N (e.g., DQ circuitry 214 of die 210-1). DQ bus 240 is an n-bit bus, which can be represented by DQ[n−1:0], where “n−1” refers to the most significant bit of a range of n bits and “O” represents the least significant bit of the range of n bits. In some implementations, DQ bus 240 is an eight-bit bus, which can be represented by DQ[7:0].

The SCA protocol implemented by system 200 allows DQ circuitry of at least one of dies 210-1 through 210-N to be separately controlled by command packets received from memory sub-system controller 115 via CA bus 230. For example, DQ circuitry of a die can power-up in a standby state, and can remain in the standby state until activated by memory sub-system controller 115. More specifically, memory sub-system controller 115 can issue at least one DQ circuitry activation command (“activation command”) to at least one target die of dies 210-1 through 210-N via CA bus 230. For example, an activation command can be an activation packet. Each activation command activates (e.g., wakes up) DQ circuitry of one or more target dies. Each activation command transitions the respective DQ circuitry from the standby state to an idle state. Each activation command can include data identifying one or more target dies (e.g., one or more addresses designating the one or more target dies). The amount of time that it takes for DQ circuitry of one or more target dies to transition to the idle state is referred to as the “activation time.” During the activation time, memory sub-system controller 115 can cause other commands to be sent to any non-target die(s) among dies 210-1 through 210-N via the CA bus, which can further improve efficiency of system 200. In some implementations, causing the other commands to be sent to any non-target die(s) includes interleaving the other commands using command sequence interleaving (e.g., as opposed to sequentially issuing the commands).

In an illustrative example, assume that die 210-1 is a target die that has received an activation command from memory sub-system controller 115. Once DQ circuitry 214 has transitioned to the standby state, die 210-1 can support a data transaction at a shorter latency than in the standby state. In some implementations, the data transaction is a data burst transaction. The receipt of the data transaction causes a transition of DQ circuitry 214 from the idle state to an active state. Memory sub-system controller 115 can issue the activation command to the die 210-1 via CA bus 230 in advance of the data transaction being issued to die 210-1 via DQ bus 240. After termination of the data transaction, DQ circuitry 214 can transition back to the standby state from the active state.

A data transaction can be controlled using pre-defined data transaction control packets that can be used to initiate, pause, resume, or terminate the data transaction. For example, the data transaction can include an initiate transaction packet indicating the beginning of the data transaction, and a terminate transaction packet indicating the end of the data transaction. In some implementations, the data transaction further includes a pause transaction packet to cause the data transaction to pause and/or a resume transaction packet to cause the data transaction to resume after a pause. In some implementations, the data transaction control packets include are defined by JEDEC standards. For example, the initiate transaction packet and the resume transaction packet can each be an SCE packet, the terminate transaction packet can be an SCT packet, and the pause transaction packet can be an SCP packet.

FIGS. 2B-2C are diagram of die 210-1, in accordance with some embodiments of the present disclosure. As shown in FIG. 2B, CA circuitry 212 can include components including CA pins 250 to receive commands from a CA bus, CE pin 252 to receive CE signals, receiver (Rx) analog circuit 254, Rx digital circuit 256, transmitter (Tx) analog circuit 258, Tx digital circuit 260, and command state machine and registers 262. For example, Rx analog circuit 254 can be implemented by an Rx 255, as well as one or more amplifiers, one or more voltage generators, and one or more analog-to-digital converters (not shown). Rx digital circuit 256 can be implemented by one or more buffers, one or more latches, and combinatorial logic. Tx analog circuit 258 can be implemented by a Tx 259, as well as one or more digital-to-analog converters, one or more voltage level-shifters, and one or more voltage generators (not shown). Tx digital circuit 260 can be implemented by one or more buffers, one or more latches, and combinatorial logic. Command state machine and registers 262 can generate an Rx control signal 264 to control Rx 255, a Tx control signal 266 to control Tx 259 and/or a DQ circuitry control signal 268 to control DQ circuitry 214 (e.g., control the state of DQ circuitry 214).

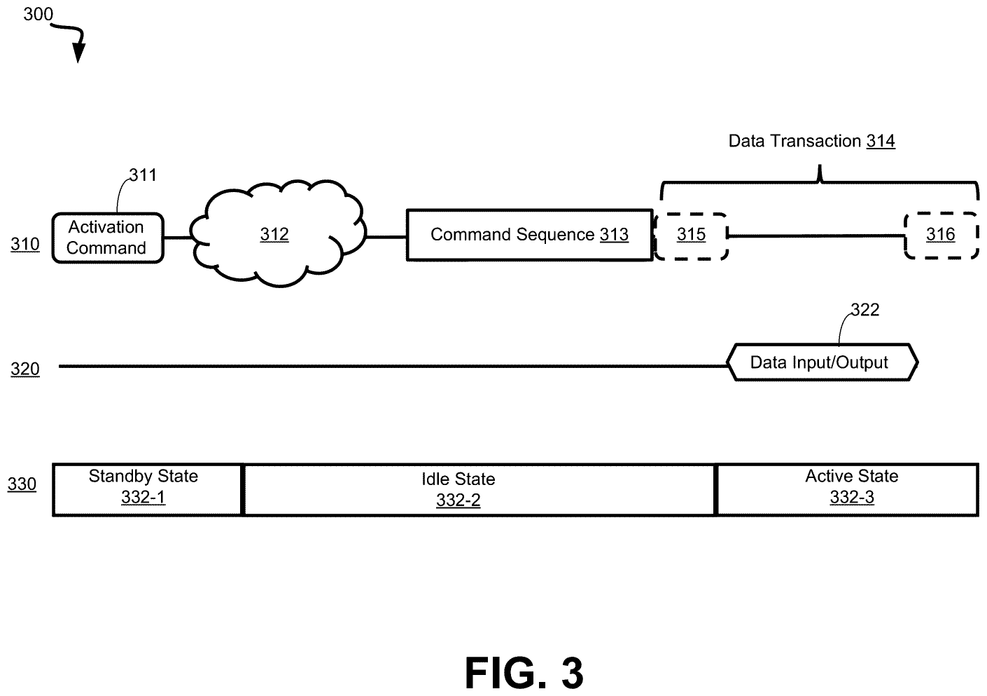

As shown in FIG. 2C, DQ circuitry 214 can include components including DQ pins 270 to receive commands via a DQ bus, Rx analog circuit 272, Rx digital circuit 274, Tx analog circuit 276, and Tx digital circuit 278. For example, Rx analog circuit 272 can be implemented by an Rx 273, as well as one or more amplifiers, one or more voltage generators, and one or more analog-to-digital converters (not shown). Rx digital circuit 274 can be implemented by one or more buffers, one or more latches, and combinatorial logic. Tx analog circuit 276 can be implemented by a Tx 277, as well as one or more digital-to-analog converters, one or more voltage level-shifters, and one or more voltage generators (not shown). Tx digital circuit 278 can be implemented by one or more buffers, one or more latches, and combinatorial logic. DQ circuitry control signal 268 can be used to control operation of one or more of circuits 272-278 to control the state of DQ circuitry 214. Rx digital circuit 274 and Tx digital circuit 278 can communicate with memory array 280 to cause data to be written to memory array 280 and/or cause data to be read out of memory array 280. Further details regarding the operations performed by system 200 of FIGS. 2A-2C will be described below with reference to FIG. 3.

FIG. 3 is a timing diagram (“diagram”) 300 illustrating an example implementation of controlling DQ circuitry power states using an SCA protocol, in accordance with some embodiments of the present disclosure. Diagram 300 shows command transactions 310 issued by a memory sub-system controller (e.g., memory sub-system controller 115 of FIGS. 1A-2) via a CA bus (e.g., CA bus 230 of FIG. 2), data transactions 320 issued by the memory sub-system controller via a DQ bus (e.g., DQ bus 240 of FIG. 2), and DQ circuitry power states 330 of DQ circuitry of a target die (e.g., DQ circuitry 214 of die 210-1 of FIG. 2). It is assumed that the target die is initially in standby state 332-1.

As shown, the memory sub-system controller issues DQ circuitry activation command (“activation command”) 311 to CA circuitry of the target die (e.g., CA circuitry 212 of die 210-1 of FIG. 2) via the CA bus. In some implementations, activation command 311 is implemented using an activation (e.g., wake up) packet. The receipt of activation packet 311 causes the DQ circuitry of the target die to transition from standby state 332-1 to idle state 332-2. In some implementations, and as shown, the memory sub-system controller can cause other commands 312 to be sent to CA circuitry of any non-target dies during the activation time of the transition from standby state 332-1 to idle state 332-2. For example, the memory sub-system controller can interleave other commands 312 to the CA circuitry of any non-target dies via the CA bus during the activation time of the transition from standby state 332-1 to idle state 332-2 (e.g., as opposed to sequentially issuing other commands 312).

As further shown, when in idle state 332-2, the memory sub-system controller can issue command sequence 313 to the command circuitry of the target memory device. For example, command sequence 313 can be a write command sequence to write data to the target die. As another example, command sequence 313 can be a read command sequence to read out data from the target die. For example, command sequence 313 can include opcode values and/or address cycle information.

As further shown, after issuing command sequence 313, the memory sub-system controller can issue data transaction 314. The receipt of data transaction 314 causes the DQ circuitry of the target die to transition from idle state 332-2 to active state 332-3. As shown, data transaction 314 includes initiate transaction command 315 indicating the beginning of the data transaction, at which point data input or data output (data input/output) 322 is sent by the memory sub-system controller via the DQ bus to the target die. For example, data input/output 322 can include one or more data items. For example, if the data transaction is a write transaction, then data input/output 322 can include one or more data items to be written to a memory array. Data transaction 314 can further include terminate transaction command 316 indicating the end of the data transaction. In some implementations, data transaction 314 further includes a pause transaction command to cause data transaction 314 to pause and/or a resume transaction command to cause data transaction 314 to resume after a pause.

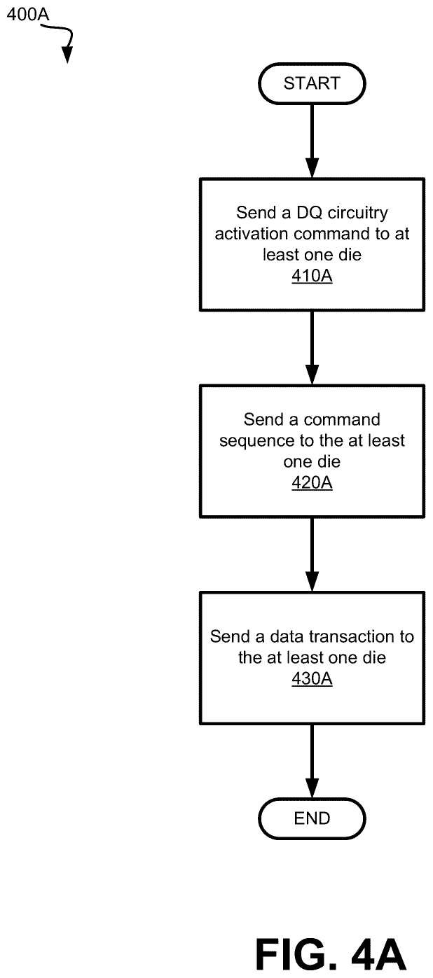

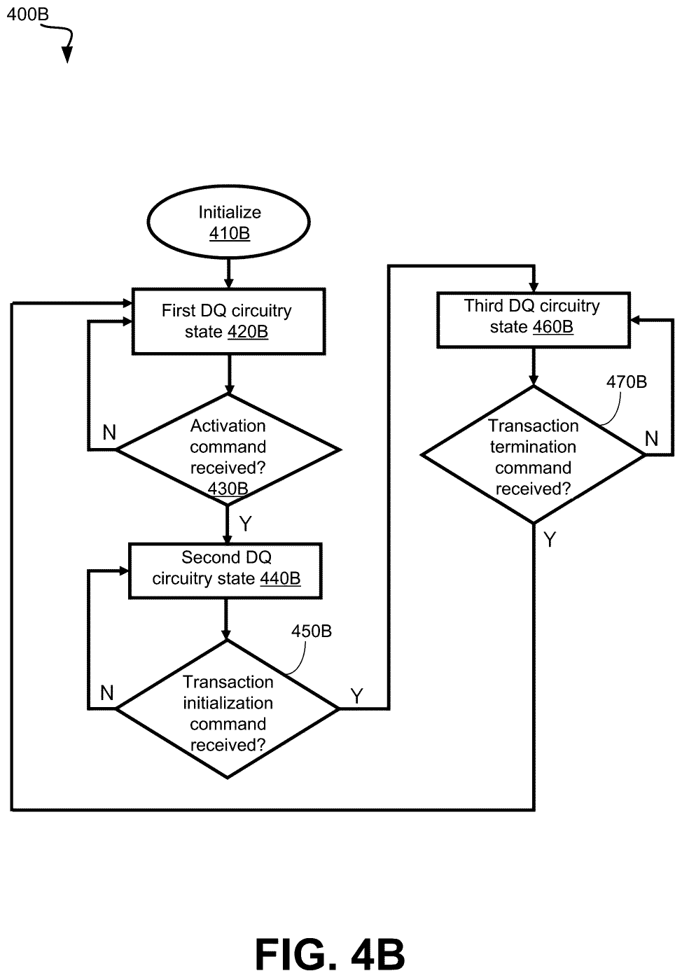

In some implementations, at least commands 315 and 316 are implemented as packets. In some implementations, at least commands 315 and 316 are defined by JEDEC standards. For example, initiate transaction command 315 can be implemented using an SCE packet, and terminate transaction command 316 can be implemented using an SCT packet. After termination of data transaction 314, the data circuitry of the target die can transition back to standby state 332-1 from active state 332-3. Further details regarding FIG. 3 are described above with reference to FIG. 2 and will now be described below with reference to FIGS. 4A-4B.

FIG. 4A is a flow diagram of an example method 400A to control DQ circuitry power states using an SCA protocol, in accordance with some embodiments of the present disclosure. Method 400A can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, method 400A is performed by the memory sub-system controller 115 of FIGS. 1A-1B.

At operation 410A, a DQ circuitry activation command (“activation command”) is sent to at least one die. For example, processing logic can cause an activation command (e.g., activation command 311 of FIG. 3) to be sent to a target die via a CA bus operatively coupled with (e.g., connected to) CA circuitry of the die. The target die can further include DQ circuitry operatively coupled with (e.g., connected to) a DQ bus. The activation command causes the target die (e.g., DQ circuitry) to transition from a first DQ circuitry state to a second DQ circuitry state. For example, the first DQ circuitry state can be a standby state and the second DQ circuitry state can be an idle state. In some implementations, the activation command is implemented using a DQ activation (e.g., DQ wake up) packet.

At operation 420A, a command sequence is sent to the at least one die. For example, processing logic can cause a command sequence (e.g., command sequence 313 of FIG. 3) to be sent to a target die, which can be received by the CA circuitry of the target die. The command sequence can be a write command sequence to write data to the target die. For example, command sequence can include opcode values and/or address cycle information.

At operation 430A, a data transaction is sent to the at least one die. For example, processing logic can cause a data transaction (e.g., data transaction 314 of FIG. 3) to be sent to a target die. The data transaction can be received by the CA circuitry of the target die. The receipt of the data transaction by the target die causes the target die (e.g., DQ circuitry) to transition from the second DQ circuitry state to a third DQ circuitry state. In some implementations, the third DQ circuitry state is an active state. The data transaction can include an initiate transaction command (e.g., initiate transaction command 315 of FIG. 3) indicating the beginning of the data transaction. For example, processing logic can cause a data input or data output (data input/output) including one or more data items (e.g., data input/output 322 of FIG. 3) to be sent to the target die via the DQ bus. The data transaction can further include a terminate transaction command (e.g., terminate transaction command 316 of FIG. 3) indicating the end of the data transaction. In some implementations, the data transaction further includes a pause transaction command to cause the data transaction to pause and/or a resume transaction command to cause the data transaction to resume after a pause.

In some implementations, at least one command of the data transaction is implemented as a packet. In some implementations, the data transaction is defined by JEDEC standards. For example, the initiate transaction command can be implemented using an SCE packet, and the terminate transaction command can be implemented using an SCT packet. After termination of the data transaction, the target die (e.g., DQ circuitry) can transition back to the first DQ circuitry state (e.g., the standby state) from the third DQ circuitry state (e.g., the active state). Further details regarding operations 410-430 are described above with reference to FIGS. 1A-3 and will now be described below with reference to FIG. 4B.

FIG. 4B is a flow diagram of an example method 400B to control DQ circuitry power states using an SCA protocol, in accordance with some embodiments of the present disclosure. Method 400B can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, method 400B is performed by the SCA component 137 of FIGS. 1A-1B.

At operation 410B, a die of a memory device is initialized. For example, processing logic can initialize the die during power-on. The die can include CA circuitry operatively coupled with (e.g., connected to) a CA bus and DQ circuitry operatively coupled with (e.g., connected to) a DQ bus.

At operation 420B, the die is placed in a first DQ circuitry state. For example, processing logic can cause the DQ circuitry to be placed in a first data circuitry state upon initialization. In some implementations, the first data circuitry state is a standby state.

At operation 430B, it is determined whether a DQ circuitry activation command (“activation command) has been received. For example, processing logic can determine whether the CA circuitry has received an activation command. The activation command can be received from a memory sub-system controller via the CA bus. In some implementations, the activation command is implemented using a DQ activation (e.g., DQ wake up) packet.

If it is determined that an activation command has not been received at operation 430B, then the die (e.g., DQ circuitry) remains in the first DQ circuitry state. Otherwise, the die is placed in a second DQ circuitry state at operation 440B. For example, processing logic can cause the DQ to transition from the first DQ circuitry state to the second DQ circuitry state. In some implementations, the second DQ circuitry state is an idle state.

At operation 450B, it is determined whether a data transaction initialization command (“transaction initialization command”) has been received. For example, processing logic can determine whether the CA circuitry has received a transaction initialization command of a data transaction. The transaction initialization command can be received from the memory sub-system controller via the CA bus. In some implementations, the transaction initialization command is implemented using a transaction initialization packet. For example, the transaction initialization packet can be an SCE packet of an SCA protocol.

If it is determined that a transaction initialization command has not been received at operation 450B, then the die (e.g., DQ circuitry) remains in the second DQ circuitry state. Otherwise, the die is placed in a third DQ circuitry state at operation 460B. For example, processing logic can cause the DQ circuitry to transition from the second DQ circuitry state to the third DQ circuitry state. In some implementations, the third DQ circuitry state is an active state. In some implementations, while in the third DQ circuitry state, processing logic can cause data to be written to the die. More specifically, the data can be received from the memory sub-system controller via the DQ bus. In some implementations, while in the third DQ circuitry state, processing logic can cause data to be read out from the die. More specifically, the data can be received by the memory sub-system controller from the die via the DQ bus.

At operation 470B, it is determined whether a data transaction termination command (“transaction termination command”) has been received. For example, processing logic can determine whether the CA circuitry has received a transaction termination command of the data transaction. The transaction termination command can be received from the memory sub-system controller via the CA bus. In some implementations, the transaction termination command is implemented using a transaction termination packet. For example, the transaction termination packet can be an SCT packet of the SCA protocol.

If it is determined that a transaction termination command has not been received at operation 470, then the die (e.g., DQ circuitry) remains in the third DQ circuitry state. Otherwise, the process can revert back to operation 420B to place the die in the first DQ circuitry state. For example, processing logic can cause the DQ circuitry to transition from the third DQ circuitry state (e.g., the active state) to the first DQ circuitry state (e.g., the standby state). Further details regarding operations 410B-470B are described above with reference to FIGS. 1A-4A.

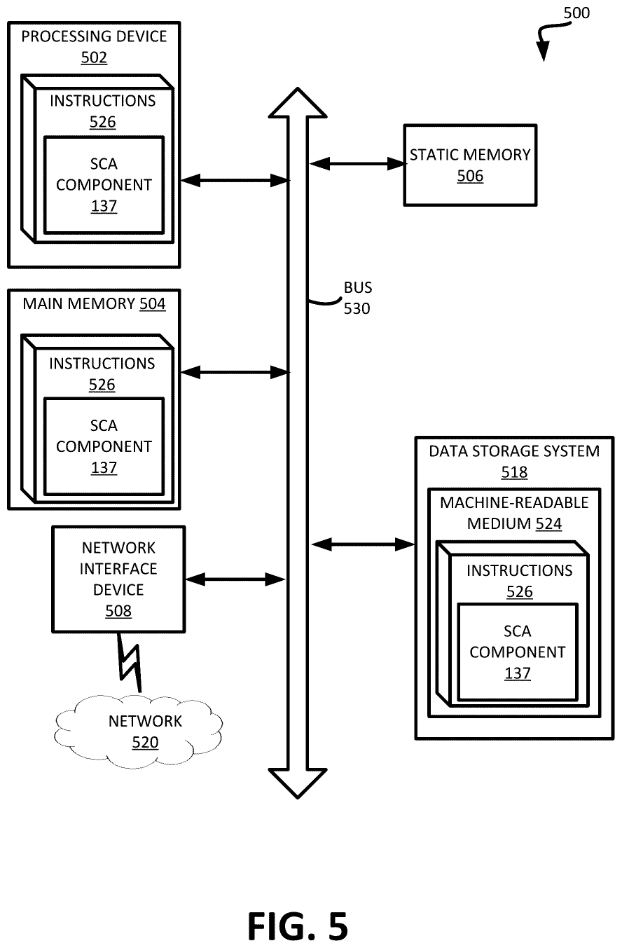

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the SCA component 137 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 404 can correspond to the memory sub-system 110 of FIG. 1A.

In one embodiment, the instructions 526 include instructions to implement functionality corresponding to a SCA component (e.g., the SCA component 137 of FIG. 1A). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of dies; and
processing logic, operatively coupled with the memory array, to perform operations comprising:
receiving a data (DQ) circuitry activation command via a command address (CA) bus operatively coupled with CA circuitry of the memory device, wherein the DQ circuitry activation command comprises data identifying a die of the plurality of dies;
in response to receiving the DQ circuitry activation command, causing DQ circuitry of the die to transition from a standby state to an idle state;
receiving, via the CA bus, a data transaction initialization command of a data transaction; and
in response to receiving the data transaction initialization command, causing the DQ circuitry to transition from the idle state to an active state.

2. The memory device of claim 1, wherein the operations further comprise causing the DQ circuitry to be placed in the standby state prior to receiving the DQ circuitry activation command.

3. The memory device of claim 1, wherein the operations further comprise, after receiving the data transaction initialization command via the CA bus, causing first data received from a memory sub-system controller via the DQ bus to be written to the die.

4. The memory device of claim 1, wherein the operations further comprise, after receiving the data transaction initialization command via the CA bus, causing second data to be read out from the die to a memory sub-system controller via the DQ bus.

5. The memory device of claim 1, wherein the operations further comprise:
receiving a data transaction termination command of the data transaction; and
in response to receiving the data transaction termination command, causing the DQ circuitry to transition from the active state to the standby state.

6. The memory device of claim 5, wherein the data transaction initialization command is implemented by a select chip enable (SCE) packet, and wherein the data transaction termination command is using select chip terminate (SCT) packet.

7. The memory device of claim 5, wherein the DQ circuitry activation command, the data transaction initialization command and the data transaction termination command are implemented using a Separate Command Address (SCA) protocol.

8. A method comprising:
receiving, by processing device, a data (DQ) circuitry activation command via a command address (CA) bus operatively coupled with CA circuitry of a memory device, wherein the DQ circuitry activation command comprises data identifying a die of the memory device;
in response to receiving the DQ circuitry activation command, causing, by the processing device, DQ circuitry of the memory device to transition from a standby state to an idle state;
receiving, by the processing device via the CA bus, a data transaction initialization command of a data transaction; and
in response to receiving the data transaction initialization command, causing, by the processing device, the DQ circuitry to transition from the idle state to an active state.

9. The method of claim 8, further comprising causing, by the processing device, the DQ circuitry to be placed in the standby state prior to receiving the DQ circuitry activation command.

10. The method of claim 8, further comprising, after receiving the data transaction initialization command via the CA bus, causing, by the processing device, first data received from a memory sub-system controller via the DQ bus to be written to the die.

11. The method of claim 8, further comprising, after receiving the data transaction initialization command via the CA bus, causing, by the processing device, second data to be read out to a memory sub-system controller via the DQ bus.

12. The method of claim 8, further comprising:
receiving, by the processing device, a data transaction termination command of the data transaction; and
in response to receiving the data transaction termination command, causing, by the processing device, the DQ circuitry to transition from the active state to the standby state.

13. The method of claim 12, wherein the data transaction initialization command is implemented by a select chip enable (SCE) packet, and wherein the data transaction termination command is using select chip terminate (SCT) packet.

14. The method of claim 12, wherein the DQ circuitry activation command, the data transaction initialization command and the data transaction termination command are implemented using a Separate Command Address (SCA) protocol.

15. A system comprising:
a memory device comprising a die, the die comprising data (DQ) circuitry operatively coupled with a DQ bus and command address (CA) circuitry operatively coupled with a CA bus and a chip enable pin; and
a memory sub-system controller operatively coupled with a data (DQ) bus, a command address (CA) bus and a chip enable pin, the memory sub-system controller comprising a processing device, operatively coupled with a memory, to perform operations comprising:
causing a DQ circuitry activation command to be sent, via the CA bus, to a die of a memory device to cause DQ circuitry of the die to transition from a standby state to an idle state; and
causing a data transaction to be sent to the die via the CA bus, the data transaction comprising a data transaction initialization command to cause the DQ circuitry to transition from the idle state to an active state, and a data transaction termination command to cause the DQ circuitry to transaction from the active state to the standby state.

16. The system of claim 15, wherein the operations further comprise causing a command sequence to be sent to the die via the CA bus prior to causing the data transaction to be sent to the die via the CA bus.

17. The system of claim 16, wherein the operations further comprise causing another command to be sent to a second die of the memory device after causing the activation command to be sent to the die and prior to causing the command sequence to be sent to the die.

18. The system of claim 15, wherein the operations further comprise at least one of:
sending, via the DQ bus, first data to be written to a memory array; or
receiving, via the DQ bus, second data read out from the memory array.

19. The system of claim 15, wherein the data transaction initialization command is implemented by a select chip enable (SCE) packet, and wherein the data transaction termination command is using select chip terminate (SCT) packet.

20. The memory device of claim 15, wherein the DQ circuitry activation command, the data transaction initialization command and the data transaction termination command are implemented using a Separate Command Address (SCA) protocol.
